(19) United States
(12) Patent Application Publication
(10) Pub. No.: US 2026/0304668 A1
(43) Pub. Date: Oct. 1, 2026

(54) GRAPHICS CARD RETENTION APPARATUSES, SYSTEMS, AND METHODS

(71) Applicant: Lenovo (United States) Inc., Morrisville, NC (US)

(72) Inventors: Jean J. Xu, Cary, NC (US); Bryan Binda, Cary, NC (US)

(21) Appl. No.: 19/094,694

(22) Filed: Mar. 28, 2025

(51) Int. Cl. H05K 7/14

(52) U.S. Cl. CPC H05K 7/1418

(57) ABSTRACT

Disclosed herein are graphics card retention apparatuses, systems, and methods. One apparatus includes a trough and a retention bracket. The trough includes a bottom structure, a pair of side walls, and an open top defining a cavity structure. The retention bracket is adjustable within a range of sizes to accommodate different sized graphics cards and to maintain a graphics card in a first horizontal direction in response to the retention bracket being butted against the graphics card. A system for graphics card retention includes the above apparatus that maintains the graphics card in the first horizontal direction and further includes a second and third apparatus that maintain the graphics card in a second horizontal direction and a vertical direction. A method includes retaining the graphics card within an external structure using the above apparatus(es).

### FIELD

The subject matter disclosed herein relates to graphics cards and, more particularly, relates to graphics card retention apparatuses, systems, and methods.

### DESCRIPTION OF THE RELATED ART

Because modern graphics cards can house more powerful graphics processing units, some graphics cards are physically larger and heavier than prior generations of graphics cards. As such, contemporary apparatus and systems for retaining graphics cards in a chassis may not provide sufficient support for modern graphics cards.

### BRIEF SUMMARY

Apparatuses for graphics card retention are disclosed herein. One apparatus includes a trough and a retention bracket. In various embodiments, the trough includes a bottom structure extending in a horizontal direction, a pair of side walls coupled to the bottom structure on opposite sides of the bottom structure and extending in a vertical direction and further extending in the horizontal direction, and an open top defining a cavity structure between the bottom structure and the pair of side walls. The retention bracket, in certain embodiments, is configured to slide along the pair of side walls in the horizontal direction to adjust a first size of the apparatus within a range of sizes to accommodate a graphics card including a second size within the range of sizes and maintain the graphics card in the horizontal direction in response to the retention bracket being butted against the graphics card.

Also disclosed are systems for graphics card retention. One system includes a first apparatus, a second apparatus, and a third apparatus. In various embodiments, the first apparatus includes a trough and a retention bracket detachably coupleable to a graphics card that includes a length size within a range of lengths and a width size within a range of widths. The retention bracket is configured to slide along the trough in a first horizontal direction to adjust a length of the first apparatus within the range of lengths to accommodate the graphics card and is further configured to maintain the graphics card in the first horizontal direction in response to the retention bracket being adjusted to include the length size and butt against a first width side of the graphics card when a second width side of the graphics card butts against an external structure. In various embodiments, the second apparatus includes a length and is coupleable to the external structure and the third apparatus coupleable to the retention bracket. In additional embodiments, the second apparatus extends in a second horizontal direction perpendicular to the first horizontal direction in response to being coupled to the external structure and the third apparatus is configured to slide along the retention bracket in the second horizontal direction to adjust a distance between the second apparatus and the third apparatus to be within the range of widths to accommodate the graphics card. In further embodiments, the second apparatus and third apparatus maintain the graphics card in the second horizontal direction in response to the distance between the second apparatus and the third apparatus including the width size, the second apparatus butting against a first length side of the graphics card, and the third apparatus butting against a second length side of the graphics card.

Further disclosed are methods for graphics card retention. One method includes providing a graphics card, coupling the graphics card to an external structure, and butting a apparatus against the graphics card in which the apparatus includes a trough and a retention bracket configured to adjustably slide along the trough and in which butting the apparatus against the graphics card secures the graphics card in place between the external structure and the apparatus within the external structure.

### BRIEF DESCRIPTION OF THE DRAWINGS

A more particular description of the embodiments briefly described above will be rendered by reference to specific embodiments that are illustrated in the appended drawings. Understanding that these drawings depict only some embodiments and are not therefore to be considered to be limiting of scope, the embodiments will be described and explained with additional specificity and detail through the use of the accompanying drawings, in which:

FIG. 1A is a schematic diagram of one embodiment of a thermal bracket that is adjustable;

FIG. 1B is schematic diagram of a portion of the thermal bracket of FIG. 1B;

FIG. 2 is schematic diagram of another embodiment of a bracket that is adjustable;

FIG. 3 is schematic diagram of yet another embodiment of a bracket that is adjustable;

FIGS. 4A through 4C are schematic block diagrams of various embodiments of a system for graphics card retention;

FIG. 5 is schematic block diagram of one embodiment of the graphics card retention system of FIG. 4C retaining one embodiment of a graphics card;

FIG. 6 is schematic block diagram of one embodiment of the graphics card retention system of FIG. 4C retaining one embodiment of a graphics card within one embodiment of a chassis; and

FIGS. 7 through 10 are schematic flow chart diagrams illustrating various embodiments of a method that can retain a graphics card.

### DETAILED DESCRIPTION

As will be appreciated by one skilled in the art, aspects of the embodiments may be embodied as a system or apparatus. Accordingly, embodiments may take the form of an entirely hardware embodiment that may all generally be referred to herein as a system.

Reference throughout this specification to one embodiment, an embodiment, or similar language means that a particular feature, structure, or characteristic described in connection with the embodiment is included in at least one embodiment. Thus, appearances of the phrases in one embodiment, in an embodiment, and similar language throughout this specification may, but do not necessarily, all refer to the same embodiment, but mean one or more but not all embodiments unless expressly specified otherwise. The terms including, comprising, having, and variations thereof mean including but not limited to, unless expressly specified otherwise. An enumerated listing of items does not imply that any or all of the items are mutually exclusive, unless expressly specified otherwise. The terms, “a,” “an,” and “the,” also refer to one or more unless expressly specified otherwise.

In addition, as used herein, the term, “set,” can mean one or more, unless expressly specified otherwise. The term, “sets,” can mean multiples of or a plurality of one or mores, ones or more, and/or ones or mores consistent with set theory, unless expressly specified otherwise.

The description of elements in each figure may refer to elements of proceeding figures. Like numbers refer to like elements in all figures, including alternate embodiments of like elements.

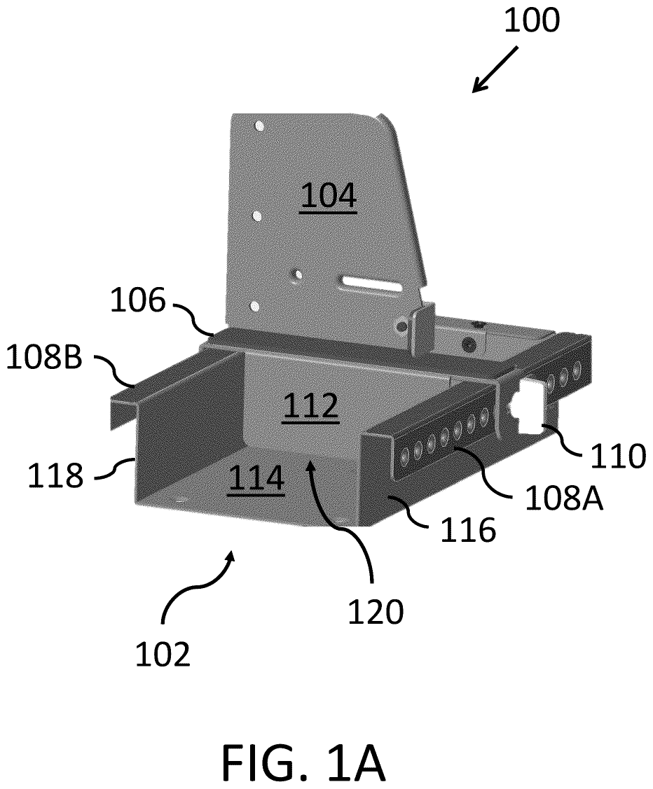

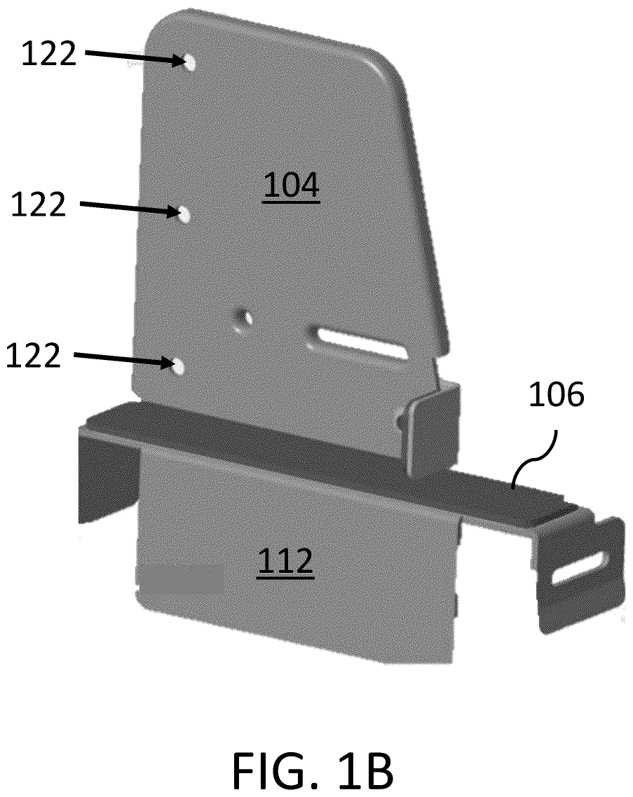

With reference to FIGS. 1A and 1B, FIG. 1A is a schematic diagram of one embodiment of an adjustable thermal bracket 100. At least in the illustrated embodiment, the adjustable thermal bracket 100 includes, among other components, a trough structure 102 (or trough 102), a retention tab 104, a support beam 106 for the retention tab 104, a set of sliding beams 108A and 108B for the support beam 106, a locking mechanism 110 for the set of sliding beams 108A and 108B, and a thermal tab 112.

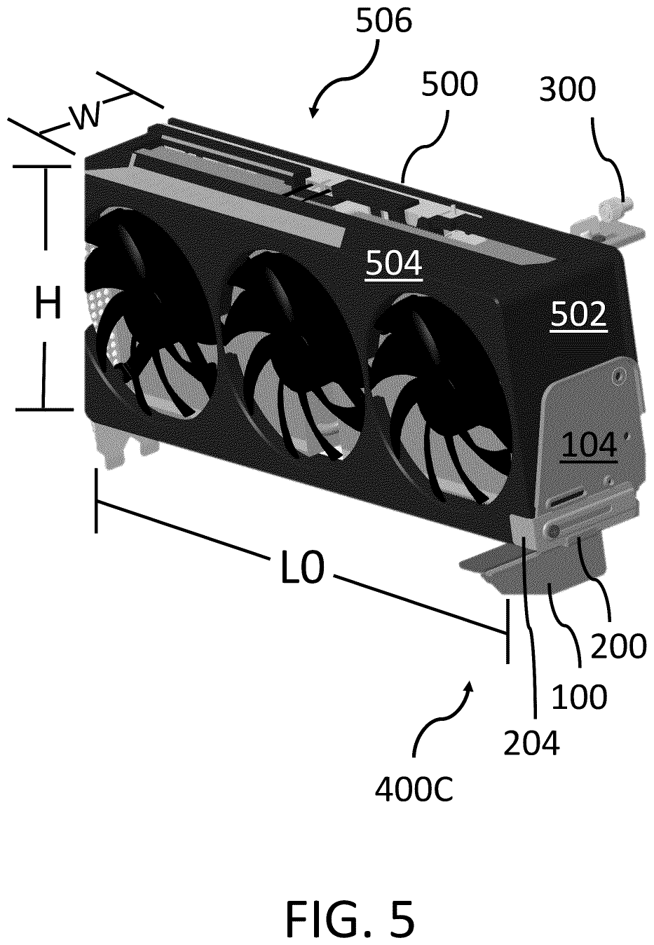

In various embodiments, the trough structure 102 includes a horizontal bottom surface 114, a vertical side wall 116, a vertical side wall 118, an open side and top defining a cavity 120. The bottom surface 114, side wall 116, and side wall 118 may include and/or be formed of any suitable material(s) that is/are known or developed in the future capable of supporting a graphics card (see, e.g., graphics card 500 in FIG. 5) mounted on and/or to the adjustable thermal bracket 100. Example suitable materials for the bottom surface 114, side wall 116, and side wall 118 can include, but are not limited to, a metal, an alloy, a carbon fiber, and/or a plastic/polymer, etc., among other suitable materials that are possible, each of which is contemplated herein.

Further, the bottom surface 114, side wall 116, and side wall 118 may each include any suitable dimension(s) (e.g., length, width, height, thickness, etc.) that is known or developed in the future capable of supporting and/or facilitating support of the graphics card 500 mounted on and/or to the adjustable thermal bracket 100. In various embodiments, the bottom surface 114, side wall 116, and side wall 118 each include one or more predetermined dimensions so that the cavity 120 includes a particular/desired size and/or volume.

The size and/or volume of the cavity 120 can allow and/or enable the graphics card 500 to be mounted on and/or to the adjustable thermal bracket 120. In addition, the size and/or volume of the cavity 120 can allow and/or enable the adjustable thermal bracket 100 to regulate and/or facilitate regulating one or more thermal properties of the graphics card 500 when mounted on and/or to the adjustable thermal bracket 100, as discussed in greater detail elsewhere herein.

A retention tab 104, as shown in FIGS. 1A and 1B, may include any suitable structure that is capable of retaining a graphics card 500. In various embodiments, the retention tab 104 includes a structure that is perpendicular or substantially perpendicular with respect to the bottom surface 114 of the trough structure 102 and/or the cavity 120 and extends vertically (e.g., extends along a Z-axis) with respect to the bottom surface 114 of the trough structure 102 and/or the cavity 120 (e.g., an X-Y axis).

The retention tab 104 may include and/or be formed of any suitable material(s) that is/are known or developed in the future capable of preventing or substantially preventing a graphics card 500 from moving laterally and/or maintaining the graphics card 500 in a particular position in response to the graphics card 500 being butted against the retention tab 104 and/or when the graphics card 500 is butted against the retention tab 104. Example suitable materials for the retention tab 104 can include, but are not limited to, a metal, an alloy, a carbon fiber, and/or a plastic/polymer, etc., among other suitable materials that are possible, each of which is contemplated herein.

In various embodiments, the retention tab 104 can include or be formed of the same material as the bottom surface 114, side wall 116, and side wall 118. In other embodiments, the retention tab 104 can include a different material than the bottom surface 114, the side wall 116, and/or the side wall 118.

Further, the retention tab 104 can include any suitable dimension(s) (e.g., length, width, height, thickness, etc.) that is known or developed in the future capable of preventing or substantially preventing the graphics card 500 from moving laterally in response to the graphics card 500 being butted against the retention tab 104 and/or when the graphics card 500 is butted against the retention tab 104. In additional or alternative embodiments, the retention tab 104 includes one or more dimensions (e.g., length, width, height, thickness, etc.) capable of maintaining and/or facilitating maintaining the graphics card 500 in a particular position in response to the graphics card 500 being butted against the retention tab 104 and/or when the graphics card 500 is butted against the retention tab 104.

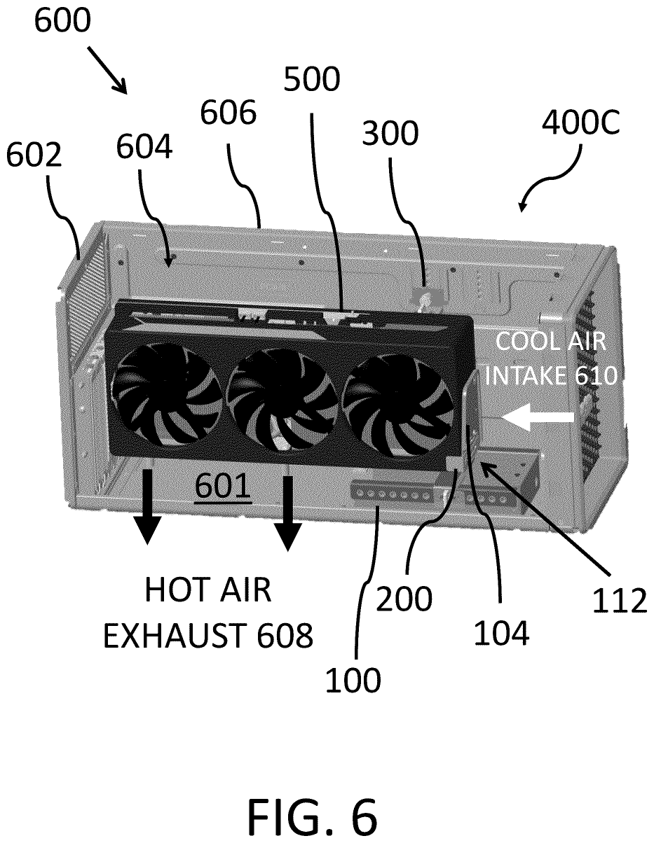

The material(s) and/or dimension(s) of the retention tab 104 can allow and/or enable the graphics card 500 to be butted against the retention tab 104/adjustable thermal bracket 100, as discussed in greater detail elsewhere herein. In addition, material(s) and/or dimension(s) of the retention tab 104 can allow and/or enable the graphics card 500 to be housed in a chassis (see, e.g., chassis 600 in FIG. 6), as discussed in greater detail elsewhere herein.

As further illustrated in FIGS. 1A and 1B, the retention tab 104 is attached/coupled to and/or mounted on the support beam 106. The support beam 106 may include and/or be formed of any suitable material(s) that is/are known or developed in the future capable of supporting the retention tab 104. Example suitable materials for the support beam 106 can include, but are not limited to, a metal, an alloy, a carbon fiber, and/or a plastic/polymer, etc., among other suitable materials that are possible, each of which is contemplated herein.

In various embodiments, the support beam 106 can include or be formed of the same material as the retention tab 104. In other embodiments, the support beam 106 can include one or more different materials than the retention tab 104.

Further, the support beam 106 can include any suitable dimension(s) (e.g., length, width, height, thickness, etc.) that is known or developed in the future capable of supporting the retention tab 104 thereon. In additional or alternative embodiments, the support beam 106 includes one or more dimensions (e.g., length, width, height, thickness, etc.) capable of allowing and/or enabling the retention tab 104 to maintain and/or facilitating maintaining the graphics card 500 in a particular position in response to the graphics card 500 being butted against the retention tab 104 and/or when the graphics card 500 is butted against the retention tab 104.

In various embodiments, the support beam 106 and the retention tab 104 can be considered the same or different components. The support beam 106 and the retention tab 104, in some embodiments, can be considered and/or can form a retention bracket.

The support beam 106, in various embodiments, capable of being attached and/or coupled to the set of sliding beams 108A and 108B. As illustrated in FIG. 1A, the sliding beams 108A and 108B are coupled/attached to and/or can form a portion of the side walls 116 and 118, respectively.

In some embodiments, the support beam 106 is permanently coupled/attached to the sliding beams 108A and 108B such that the support beam 106 cannot be removed from the sliding beams 108A and 108B. In various embodiments, the sliding beams 108A and 108B and the support beam 106 can be considered the same or different components.

In other embodiments, the support beam 106 is detachably coupleable (e.g., can be attached/coupled to and subsequently decoupled/detached from) to one or more of the sliding beams 108A and 108B. That is, the support beam 106 can be coupled/attached to and decoupled/detached from one or both sliding beams 108A and 108B.

The sliding beams 108A and 108B, in various embodiments, can extend along an entire length of the side walls 116 and 118 or a portion of the length of the side walls 116 and 118, respectively. In addition, the sliding beams 108A and 108B can include any suitable structure that allows and/or enables the sliding beams 108A and 108B to travel and/or move laterally along the length of the side walls 116 and 118, respectively.

At least in the illustrated embodiment, the sliding beams 108A and 108B can each include a tray structure, among other suitable structures that are possible, each of which is contemplated herein. The tray structure in the sliding beam 108A can create a space or gap between the sliding beam 108A and the side wall 116. Likewise, the tray structure in the sliding beam 108B can create a space or gap between the sliding beam 108B and the side wall 118.

The sliding beams 108A and 108B operating in conjunction with the support beam 106 can provide the adjustability aspect and/or elements of the adjustable thermal bracket 100. That is, the tray structure of the sliding beams 108A and 108B can allow and/or enable the support beam 106 to slide along the length of the side walls 116 and 118 so that different sized graphics cards 500 can be housed within a chassis 600, as discussed in greater detail elsewhere herein.

The sliding beams 108A and 108B operating in conjunction with the support beam 106 can allow/enable any suitable sized graphics card 500 to be housed within a chassis 600. In various embodiments, the sliding beams 108A and 108B operating in conjunction with the support beam 106 are adjustable within a range of lengths from about 245 mm to about 360 mm, among other lengths that are smaller than 245 mm and/or greater than 360 mm that are possible, each of which is contemplated herein. That is, the sliding beams 108A and 108B operating in conjunction with the support beam 106 can create a space/length between a wall of a chassis 600 (see, e.g., chassis wall 602 in FIG. 6) and the retention tab 104 to house/accommodate a graphics card 500 that includes a length L0 (see, FIG. 5) in the range of about 245 mm to about 360 mm.

A locking mechanism 110, as shown in FIG. 1A, can include any suitable structure that can lock at least one of the sliding beams 108A and 108B in place and/or prevent the sliding beams 108A and 108B from moving when engaged. The locking mechanism 110 may include any lock, type of lock, locking device, type of locking device, locking mechanism, and/or type of locking mechanism that is known or developed in the future. Example locking mechanisms can include, but are not limited to, a stop lock, a pin, a clamp, a screw, and/or a nail, etc., among other locking mechanisms that are possible, each of which is contemplated herein.

In various embodiments, the locking mechanism 110 is configured to lock in place at least one of the sliding beams 108A and 108B and/or prevent the sliding beams 108A and 108B from moving/sliding in response to the locking mechanism 110 being engaged. In further embodiments, the locking mechanism 110 is configured to allow/enable the sliding beams 108A and 108B to move/slide in response to the locking mechanism 110 being disengaged.

In some embodiments, the locking mechanism 110 can be engaged/disengaged by hand (e.g., without the use of one or more tools). In additional or alternative embodiments, the sliding beams 108A and 108B can be slide and/or moved along the side walls 116 and 118 by hand.

A thermal tab 112, as shown in FIGS. 1A and 1B, may include any suitable structure that is capable of creating a thermal barrier between two areas and/or environments surrounding a graphics card 500. In various embodiments, the thermal tab 112 includes a structure that is perpendicular or substantially perpendicular with respect to the bottom surface 114 of the trough structure 102 and extends down vertically (e.g., extends along a Z-axis) from the bottom surface of the support beam 106 toward the bottom surface 114 of the trough structure 102 (e.g., an X-Y axis).

The thermal tab 112 may include and/or be formed of any suitable material(s) that is/are known or developed in the future capable of preventing or substantially preventing a thermal exchange between at least two areas and/or environments proximate to and/or adjacent to the graphics card 500 in response to the graphics card 500 being butted against the retention tab 104 and/or when the graphics card 500 is butted against the retention tab 104. Example suitable materials for the thermal tab 112 can include, but are not limited to, a metal, an alloy, a carbon fiber, and/or a plastic/polymer, etc., among other suitable materials that are possible, each of which is contemplated herein.

In various embodiments, the thermal tab 112 can include or be formed of the same material as the retention tab 104, support beam 106, bottom surface 114, side wall 116, and side wall 118. In other embodiments, the thermal tab 112 can include a different material than the retention tab 104, support beam 106, bottom surface 114, the side wall 116, and/or the side wall 118.

The thermal tab 112 can include any suitable dimensions (e.g., length, width, height, thickness, etc.) that allow and/or enable the thermal tab 112 to be housed within the cavity 120 formed by the trough 102. Further, the thermal tab 112 can include any suitable dimension(s) that is known or developed in the future capable of preventing or substantially preventing a thermal exchange between at least two areas and/or environments proximate to and/or adjacent to the graphics card 500 in response to the graphics card 500 being butted against the retention tab 104 and/or when the graphics card 500 is butted against the retention tab 104 and the thermal tab 112 is housed in the cavity 120. In additional or alternative embodiments, the thermal tab 112 includes one or more dimensions (e.g., length, width, height, thickness, etc.) capable of maintaining and/or facilitating maintaining the thermal tab 112 within the cavity 120 as the support beam 106 is moved/slide along the sliding beams 108A and 108B while the locking mechanism 110 is disengaged and/or when the thermal tab 112 is stationary within the cavity 120 while the locking mechanism 110 is engaged.

In some embodiments (see, e.g., FIG. 1A), the thermal tab 112 is configured to form at least a portion of a wall of the cavity 120. Here, the thermal tab 112 can form and/or provide a thermal divider (or thermal barrier) between the hot air exhaust and the cool air intake for the graphics card 500, as discussed in greater detail elsewhere herein.

With reference to FIG. 1B, the retention tab 104 includes a set of mounting apertures 122 (or mounting holes). The retention tab 104 may include any suitable quantity of mounting apertures 122, each mounting aperture 122 can include any suitable size/dimension(s), and/or the mounting aperture(s) 122 can be positioned in any suitable location(s) that can enable the retention tab 104 to be coupled/mounted to a graphics card 500.

In various embodiments, an attachment mechanism (not shown) can be inserted into a mounting aperture 122 to couple and/or attach the retention tab 104 to a graphics card 500, which can include any suitable attachment mechanism that is known or developed in the future. In some embodiments, the attachment mechanism can include a screw, among other attachment mechanisms and/or types of attachment mechanisms that are possible, each of which is contemplated herein.

While the illustrated embodiment includes three (3) mounting apertures 122, the various embodiments are not limited to three mounting apertures 122. That is, various embodiments can include a greater quantity or a smaller quantity of mounting apertures 122 than three mounting apertures 122.

In certain embodiments, the retention tab 104 includes a set of mounting apertures 122 in respective positions that line up with apertures/holes of a graphics card 500 manufactured by Nvidia® Corporation of Santa Clara, California. Here, the set of mounting apertures 122 on the retention tab 104 can be considered to include one or more specifications in accordance with the Nvidia® standard, among other specifications and/or standards that are possible, each of which is contemplated herein.

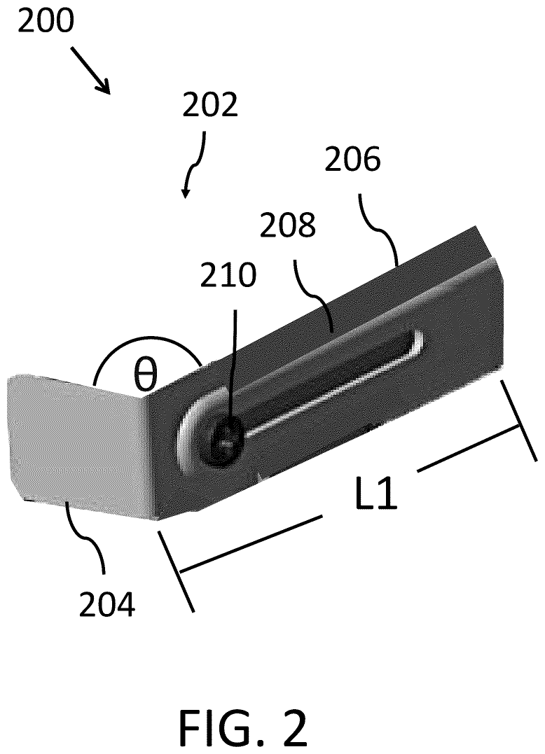

FIG. 2 is a schematic diagram of one embodiment of an adjustable bracket 200. At least in the illustrated embodiment, the bracket 200 includes an L-shape 202 and can be referred to as an L-bracket, an angle bracket, and/or a corner bracket.

At least in the illustrated embodiment, the bracket 200 is formed by an arm 204 and an arm 206 that are separated by an angle θ. The arm 204 may include any suitable length that in known or developed in the future and the angle θ may include any suitable angle that is known or developed in the future (e.g., about 45 degrees to about 90 degrees) capable of maintaining a graphics card 500 in place and/or preventing/substantially preventing the graphics card 500 from moving within a chassis 600.

In various embodiments, the arm 206 includes an adjustment mechanism 208 such that the arm 206 includes an adjustable length L1. The adjustment mechanism 208 may include any suitable mechanism that can adjust the length L1 within a range of lengths.

The adjustable length L1 can include any suitable adjustable length that is known or developed in the future capable of maintaining a width W (see, e.g., FIG. 5) of a graphics card 500 in place and/or preventing/substantially preventing the graphics card 500 from moving within a chassis 600. In various embodiments, the length L1 is adjustable via the adjustment mechanism 208 within a range of lengths to accommodate the width W of three (3) graphics cards 500 (e.g., threes slots wide in the chassis 600) to about five (5) graphics cards 500 (e.g., five slots wide in the chassis 600), among other lengths that are capable of housing/restraining a smaller quantity of graphics cards 500 (or slots in the chassis 600) than three graphics cards 300 or a greater quantity of graphics cards 500 (or slots in the chassis 600) than five graphics cards 500 that are possible, each of which is contemplated herein. That is, as the length L1 increases a greater quantity of graphics card widths W (or slot widths in the chassis 600) can be restrained by the bracket 200. Similarly, as the length L1 decreases a smaller quantity of graphics card widths W (or slot widths in the chassis 600) can be restrained by the bracket 200.

In various embodiments, the bracket 200 and/or adjustment mechanism 208 includes a locking mechanism 210. The locking mechanism 210 can include any suitable structure that can lock the adjustment mechanism 208 in place and/or prevent the adjustment mechanism 208 from moving when engaged. The locking mechanism 210 may include any lock, type of lock, locking device, type of locking device, locking mechanism, and/or type of locking mechanism that is known or developed in the future. Example locking mechanisms can include, but are not limited to, a stop lock, a pin, a clamp, a screw, and/or a nail, etc., among other locking mechanisms that are possible, each of which is contemplated herein.

In various embodiments, the locking mechanism 210 is configured to lock in place the adjustment mechanism 208 and/or prevent the arm 206 from changing the length L1 in response to the locking mechanism 210 being engaged. In further embodiments, the locking mechanism 210 is configured to allow/enable the adjustment mechanism 208 to move/slide and/or the arm 206 to change length L1 (e.g., increase/decrease length L1) in response to the locking mechanism 210 being disengaged.

In some embodiments, the locking mechanism 210 can be engaged/disengaged by hand (e.g., without the use of one or more tools). In additional or alternative embodiments, the adjustment mechanism 208 can be moved/slide and/or the length L1 of the arm 206 can be changed (e.g., increase/decrease length L1) by hand.

The bracket 200 may include any suitable other dimension(s) (e.g., width, height, thickness, etc.) that is known or developed in the future capable of supporting and/or restraining the graphics card 500 in the chassis 600. Further, the bracket 200 may include and/or be formed of any suitable material(s) that is/are known or developed in the future capable of supporting and/or restraining a graphics card 500. Example suitable materials for the bracket 200 can include, but are not limited to, a metal, an alloy, a carbon fiber, and/or a plastic/polymer, etc., among other suitable materials that are possible, each of which is contemplated herein.

In various embodiments, the bracket 200 can include or be formed of the same material as the thermal bracket 100. In other embodiments, the bracket 200 can include one or more different materials than the thermal bracket 100.

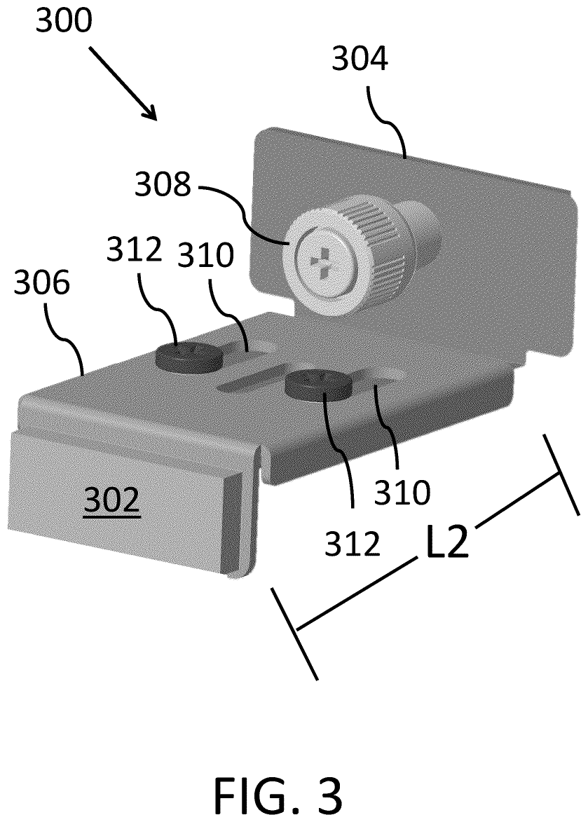

FIG. 3 is a schematic diagram of another embodiment of an adjustable bracket 300. At least in the illustrated embodiment, the bracket 300 includes, among other components, a vertical front plate 302, a vertical back plate 304, and a horizontal plate 306 coupled to one another.

The front plate 302 can include any suitable dimensions (e.g., length, width, height, thickness, etc.) that allow and/or enable one or more graphics cards 500 to be housed within a chassis 600. Further, the front plate 302 can include any suitable dimension(s) that is known or developed in the future capable of preventing or substantially preventing one or more graphics cards 500 from moving in a lateral direction and/or vertical direction within the chassis 600 in response to the graphics card 500 being butted against the front plate 302. In additional or alternative embodiments, the front plate 302 includes one or more dimensions (e.g., length, width, height, thickness, etc.) capable of maintaining and/or facilitating maintaining the graphics card(s) 500 in place within the chassis 600 in response to the front plate 302 and graphics card(s) 500 being butted against each other.

The back plate 304 can include any suitable dimensions (e.g., length, width, height, thickness, etc.) that allow and/or enable the back plate 304 to be coupled to and/or mounted to a chassis 600. Further, the back plate 304 can include any suitable dimension(s) that is known or developed in the future capable of preventing or substantially preventing one or more graphics cards 500 from moving in a lateral direction and/or vertical direction within the chassis 600 in response to the graphics card 500 being butted against the front plate 302 and the back plate 304 being coupled/mounted to the chassis 600. In additional or alternative embodiments, the back plate 304 includes one or more dimensions (e.g., length, width, height, thickness, etc.) capable of maintaining and/or facilitating maintaining the graphics card(s) 500 in place within the chassis 600 in response to the front plate 302 and graphics card(s) 500 being butted against each other and the back plate 304 is coupled/mounted to the chassis 600.

In various embodiments, the back plate 304 is coupled/mounted to the chassis 600 via a locking mechanism 308. The locking mechanism 308 can include any suitable structure that can lock/couple the bracket 300 in place and/or prevent the bracket 300 from moving when engaged with the chassis 600. The locking mechanism 308 may include any lock, type of lock, locking device, type of locking device, locking mechanism, and/or type of locking mechanism that is known or developed in the future. Example locking mechanisms can include, but are not limited to, a stop lock, a pin, a clamp, a screw, and/or a nail, etc., among other locking mechanisms that are possible, each of which is contemplated herein.

In various embodiments, the locking mechanism 308 is configured to lock in place the bracket 300 and/or prevent the bracket 300 from moving in response to the locking mechanism 308 being engaged with the chassis 600. In further embodiments, the locking mechanism 308 is configured to allow/enable removal of the bracket 300 from the chassis 600 in response to the locking mechanism 308 being disengaged from the chassis 600.

In some embodiments, the locking mechanism 308 can be engaged/disengaged by hand (e.g., without the use of one or more tools). In additional or alternative embodiments, the bracket 300 can be removed from the chassis 600 by hand.

At least in the illustrated embodiment, the horizontal plate 306 is positioned between the front plate 302 and the back plate 304. In various embodiments, the horizontal plate 306 includes a set of one or more adjustment mechanisms 310 such that the horizontal plate 306 includes an adjustable length L2. The adjustment mechanism(s) 310 may include any suitable mechanism that can adjust the length L2 within a range of lengths.

The adjustable length L2 can include any suitable adjustable length that is known or developed in the future capable of creating/maintaining space between a length side of a graphics card 500 and a chassis 600. In various embodiments, the length L2 is adjustable via the adjustment mechanism(s) 310 within a range of lengths so that the graphics card 500 is positioned within a range of distances from a wall of the chassis 600 (see, e.g., chassis wall 606 in FIG. 6). That is, as the length L2 increases a greater amount of space exists/is created between the graphics card 500 and the chassis wall 606. Similarly, as the length L2 decreases a smaller amount of space exists/is created between the graphics card 500 and the chassis wall 604.

While the illustrated embodiment includes two (2) adjustment mechanism(s) 310, the various embodiments are not limited to two adjustment mechanism(s) 310. That is, other embodiments can include a single adjustment mechanism 310 or any suitable quantity of adjustment mechanisms 310 greater than two adjustment mechanisms 310.

In various embodiments, the bracket 300 and/or each adjustment mechanism 310 includes a locking mechanism 312. A locking mechanism 312 can include any suitable structure that can lock the adjustment mechanism 310 in place and/or prevent the adjustment mechanism 310 from moving when engaged. The locking mechanism 312 may include any lock, type of lock, locking device, type of locking device, locking mechanism, and/or type of locking mechanism that is known or developed in the future. Example locking mechanisms can include, but are not limited to, a stop lock, a pin, a clamp, a screw, and/or a nail, etc., among other locking mechanisms that are possible, each of which is contemplated herein.

In various embodiments, the locking mechanism 312 is configured to lock in place the adjustment mechanism 310 and/or prevent the horizontal plate 306 from changing the length L2 in response to the locking mechanism 312 being engaged. In further embodiments, the locking mechanism 312 is configured to allow/enable the adjustment mechanism 310 to move/slide and/or the horizontal plate 306 to change length L2 (e.g., increase/decrease length L2) in response to the locking mechanism 312 being disengaged.

In some embodiments, the locking mechanism 312 can be engaged/disengaged by hand (e.g., without the use of one or more tools). In additional or alternative embodiments, the adjustment mechanism 310 can be moved/slide and/or the length L2 of the horizontal plate 306 can be changed (e.g., increase/decrease length L2) by hand.

The bracket 300 may include any suitable other dimension(s) (e.g., width, height, thickness, etc.) that is known or developed in the future capable of supporting and/or restraining the graphics card 500 in the chassis 600. Further, the bracket 300 may include and/or be formed of any suitable material(s) that is/are known or developed in the future capable of supporting and/or restraining a graphics card 500. Example suitable materials for the bracket 200 can include, but are not limited to, a metal, an alloy, a carbon fiber, and/or a plastic/polymer, etc., among other suitable materials that are possible, each of which is contemplated herein.

In various embodiments, the vertical front plate 302, vertical back plate 304, and horizontal plate 306 can include or be formed of the same material. In other embodiments, the vertical front plate 302, vertical back plate 304, and horizontal plate 306 can include one or more different materials than each other.

In various embodiments, the bracket 300 can include or be formed of the same material as the thermal bracket 100 and/or the bracket 200. In other embodiments, the bracket 300 can include one or more different materials than the thermal bracket 100 and/or the bracket 200.

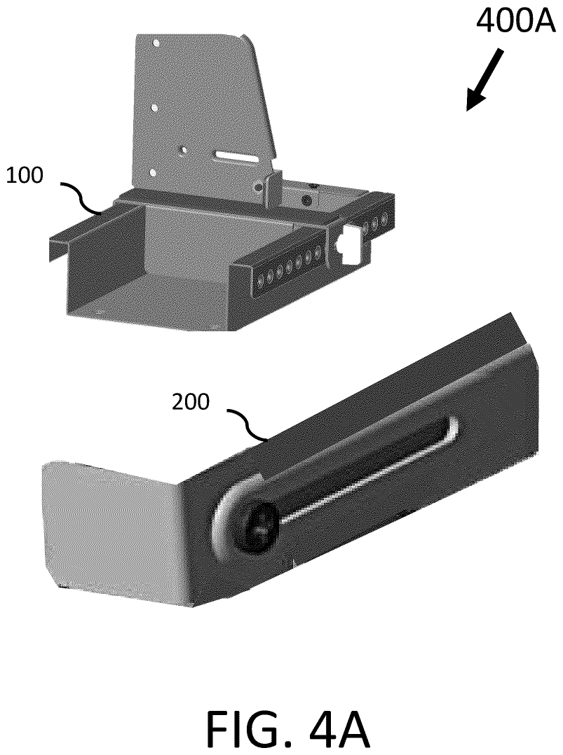

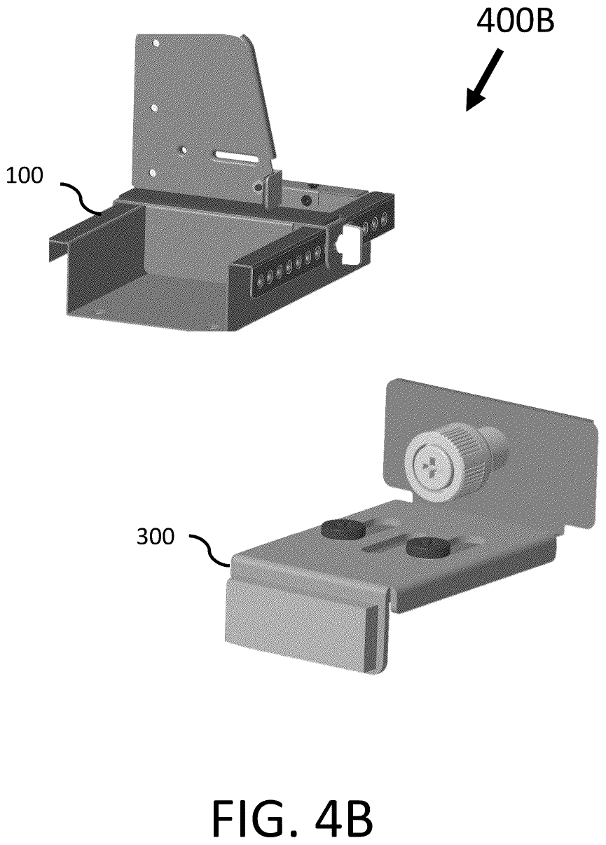

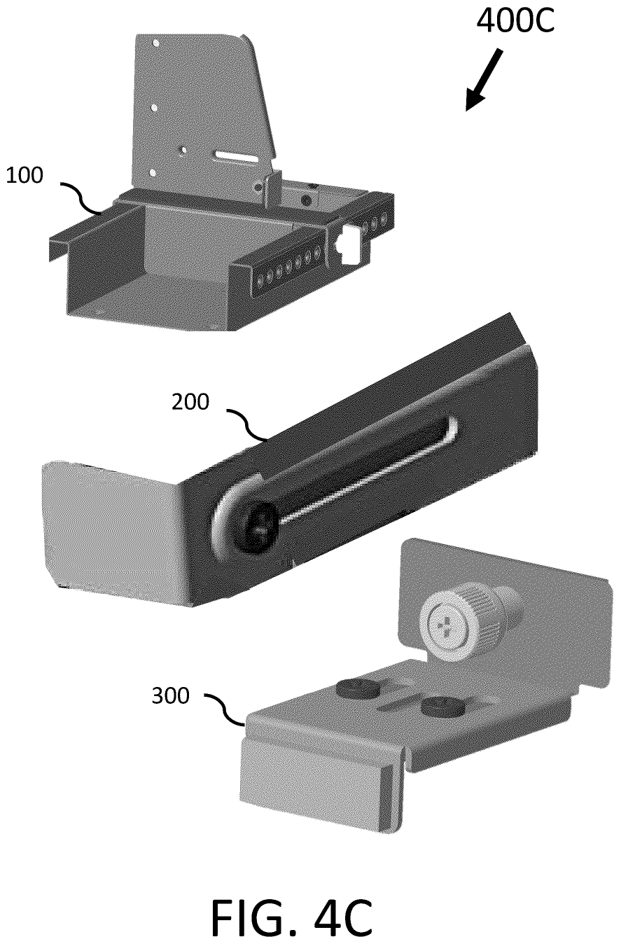

FIG. 4A is a schematic diagram of one embodiment of a system 400A for graphics card retention. At least in the illustrated embodiment, the system 400A includes, among other components, a thermal bracket 100 and a bracket 200.

The thermal bracket 100 may include any embodiment of the thermal bracket 100 discussed elsewhere herein. Similarly, the bracket 200 may include any embodiment of the bracket 200 discussed elsewhere herein.

FIG. 4B is a schematic diagram of another embodiment of a system 400B for graphics card retention. At least in the illustrated embodiment, the system 400B includes, among other components, a thermal bracket 100 and a bracket 300.

The thermal bracket 100 may include any embodiment of the thermal bracket 100 discussed elsewhere herein. Similarly, the bracket 300 may include any embodiment of the bracket 300 discussed elsewhere herein.

FIG. 4C is a schematic diagram of a further embodiment of a system 400C for graphics card retention. At least in the illustrated embodiment, the system 400C includes, among other components, a thermal bracket 100, a bracket 200, and a bracket 300.

The thermal bracket 100 may include any embodiment of the thermal bracket 100 discussed elsewhere herein. Similarly, the bracket 200 may include any embodiment of the bracket 200 discussed elsewhere herein. In addition, the bracket 300 may include any embodiment of the bracket 300 discussed elsewhere herein.

FIG. 5 is a schematic diagram of one embodiment of a system 400C that can retrain a graphics card 500. As discussed elsewhere herein, the system 400C includes, among other components, a thermal bracket 100, a bracket 200, and a bracket 300.

The thermal bracket 100 may include any embodiment of the thermal bracket 100 discussed elsewhere herein. Similarly, the bracket 200 may include any embodiment of the bracket 200 discussed elsewhere herein. In addition, the bracket 300 may include any embodiment of the bracket 300 discussed elsewhere herein.

As illustrated, the retention tab 104 of the thermal bracket 100 butts up against a width side 502 of the graphics card 500. Here, the retention tab 104 can prevent the graphics card 500 from moving in the length direction (e.g., along the length L) past the retention tab 104 and/or maintain the position of the graphics card 500.

The arm 204 of the bracket 200 butts up against a length side 504 of the graphics card 500. Here, the arm 204 can prevent the graphics card 500 from moving in the width direction (e.g., along the width W) past the arm 204 and/or maintain the position of the graphics card 500.

The bracket 300 butts against a length side 506 of the graphics card 500 that is opposite the length side 504 of the graphics card 500. Here, the bracket 300 (e.g., front plate 302, not shown) can prevent the graphics card 500 from moving in the width direction (e.g., along the width W) past the bracket 300 and/or maintain the position of the graphics card 500.

In addition, the arm 204 and the bracket 300 can prevent the graphics card 500 from moving in the height direction (e.g., along the height H of the graphics card 500). Further, the arm 204 and the bracket 300 can maintain the position of the graphics card 500.

As illustrated in FIG. 5, the arm 204 and the bracket 300 are positioned at different heights H of the graphics card 500. In some embodiments, the bracket 300 is oriented at a higher height H of the graphics card 500 than the arm 204. The bracket 300 can be oriented at any suitable height H of the graphics card 500. In some embodiments, the bracket 300 is orient at a height of 190 mm in the height H of the graphics card 500.

In other embodiments, the arm 204 is oriented at a higher height H of the graphics card 500 than the bracket 300. In other embodiments, the arm 204 and the bracket can be oriented at the same height H of the graphics card 500.

FIG. 6 is a schematic diagram of the system 400C retaining a graphics card 500 in a chassis 600. As discussed elsewhere herein, the system 400C includes, among other components, a thermal bracket 100, a bracket 200, and a bracket 300.

In the system 400C, the thermal bracket 100 is coupled to the chassis 600 (e.g., a floor 601 of the chassis 600) and may include any embodiment of the thermal bracket 100 discussed elsewhere herein. Similarly, the bracket 200 may include any embodiment of the bracket 200 discussed elsewhere herein. In addition, the bracket 300 may include any embodiment of the bracket 300 discussed elsewhere herein.

Similar to the embodiment of FIG. 5, the retention tab 104 of the thermal bracket 100 butts up against a width side of the graphics card 500. In addition, the opposite width side of the graphics card butts against a chassis wall 602 of the chassis. Here, the retention tab 104 and the chassis wall 602 can prevent the graphics card 500 from moving in the length direction (e.g., along the length L) and/or maintain the position of the graphics card 500 in the chassis 600.

The arm 204 of the bracket 200 butts up against a length side of the graphics card 500 and the bracket 300 butts against an opposite length side of the graphics card 500. Here, the arm 204 and the bracket 300 can prevent the graphics card 500 from moving in the width direction (e.g., along the width W) and/or from moving in the height direction (e.g., along the height H). Further, the arm 204 and the bracket 300 can maintain the position of the graphics card 500 in the chassis 600.

As illustrated in FIG. 6, the arm 204 and the bracket 300 are positioned at different heights H of the graphics card 500. In some embodiments, the bracket 300 is oriented at a higher height H of the graphics card 500 than the arm 204. The bracket 300 can be oriented at any suitable height H of the graphics card 500. In some embodiments, the bracket 300 is orient at a height of 190 mm in the height H of the graphics card 500.

Further illustrated in FIG. 6, the bracket 300 can create a space 604 between the graphics card 500 and a wall 606 of the chassis 600. The space 604 may include any suitable dimensions (e.g., length, width, height, volume, area, etc.) that can enable/allow the graphics cards 500 to be housed within the chassis 600 and/or to assist in ventilation of the graphics card 500, as discussed elsewhere herein.

A chassis 600 may include any suitable structure, chassis, and/or type of chassis that is known or developed in the future that can house a graphics card 500 therein. In some embodiments, the chassis 600 includes a structure that can support a set of one or more Peripheral Component Interconnect (PCI) devices. In other embodiments, the chassis 600 includes a structure that can support a set of one or more PCI Express (PCIe) devices.

FIG. 6 also shows how a thermal tab 112 of the thermal bracket 100 can provide a thermal divider/barrier for the graphics card 500 and/or chassis 600. Here, as the graphics tab 500 operates, the graphics card 500 generates heat that exits the graphics card 500 via a hot air exhaust 608. The hot air exhaust 608 can be located at a bottom of the graphics card 500, among other locations that are possible, each of which is contemplated herein.

Further, as the graphics card 500 operates, the graphics card 500 draws in cool air via a cool air intake 610. The cool air intake 610 can be located at a lateral side of the graphics card 500, among other locations that are possible, each of which is contemplated herein.

As shown in FIG. 6, the thermal tab 112 of the thermal bracket 100 is positioned between the hot air exhaust 608 and the cool air intake 610. In this manner, the thermal tab 112 provides a physical barrier between the hot air exhaust 608 and the cool air intake 610, which also creates a thermal barrier between the heat dissipating at the hot air exhaust 608 and the cool air being drawn in at the cool air intake 610 so that the heat and the cool air do not mix with one another.

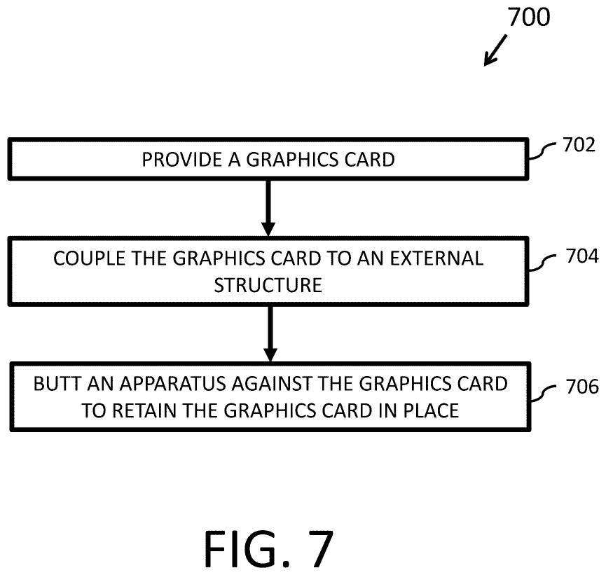

FIG. 7 is a schematic flow diagram of one embodiment of a method 700 for graphics card retention. At least in the illustrated embodiment, the method 700 begins by providing a graphics card 500 (block 702).

The graphics card 500 is coupled to an external structure (block 704). In some embodiments, the external structure includes the chassis 600.

An apparatus is butted against the graphics card 500 to retain the graphics card 500 within the chassis 600 (block 706). In some embodiments, the apparatus includes the thermal bracket 100.

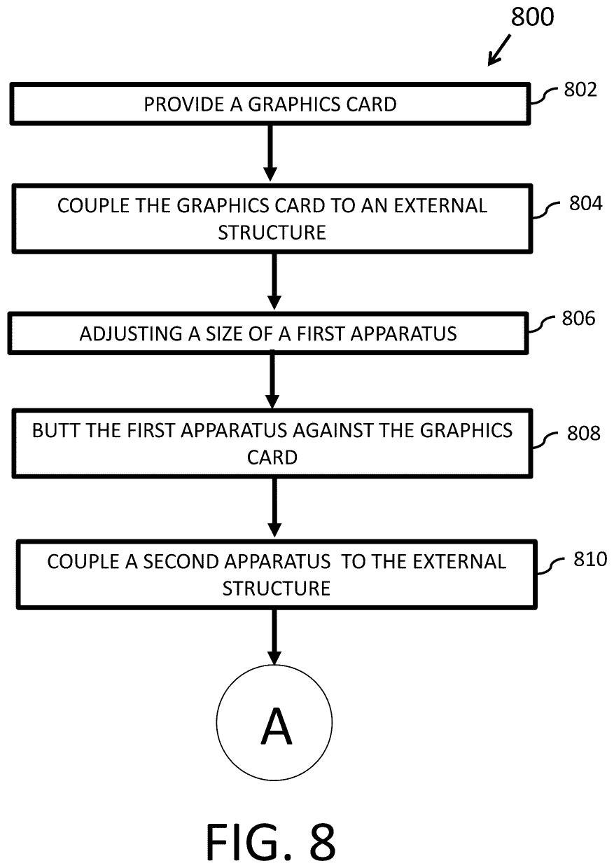

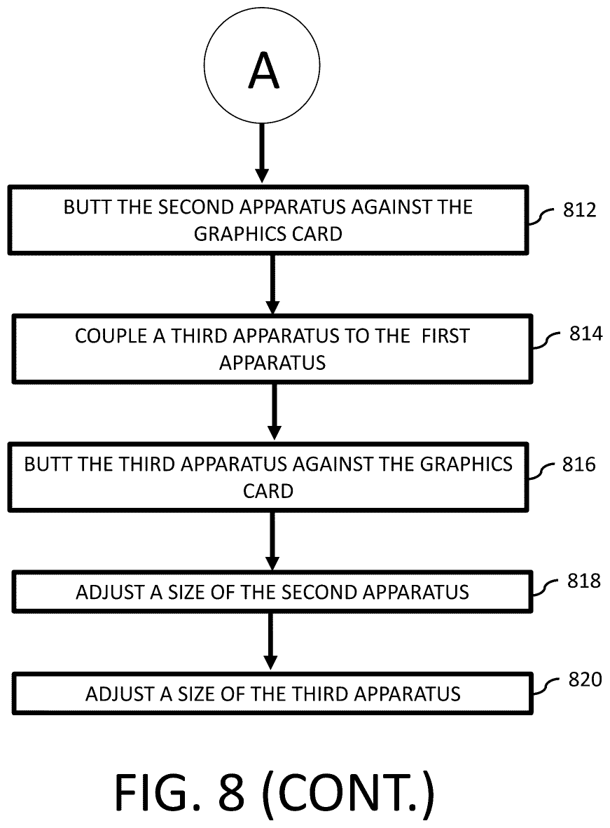

FIG. 8 is a schematic flow diagram of another embodiment of a method 800 for graphics card retention. At least in the illustrated embodiment, the method 800 begins by providing a graphics card 500 (block 802).

The graphics card 500 is coupled to an external structure (block 804). In some embodiments, the external structure includes the chassis 600.

The size of a first apparatus is adjusted so that the graphics card 500 can be housed within the chassis 600 (block 806). In some embodiments, the first apparatus includes the thermal bracket 100.

The thermal bracket 100 is butted against the graphics card 500 to retain the graphics card 500 within the chassis 600 and/or so that the graphics card 500 is prevented from moving in a first lateral/horizontal direction (e.g., an x-axis direction or a y-axis direction) in the chassis 600 (block 808).

A second apparatus is coupled to the chassis 600 (block 810) and butted against the graphics card 500 to retain the graphics card 500 within the chassis 600 and/or so that the graphics card 500 is prevented from moving in a second lateral/horizontal direction (e.g., an x-axis direction or a y-axis direction) in the chassis 600 that is perpendicular to the first lateral/horizontal direction (block 812). In some embodiments, the second apparatus includes the bracket 200.

A third apparatus is coupled to the thermal bracket 100 (block 814) and butted against the graphics card 500 to retain the graphics card 500 within the chassis 600 and/or so that the graphics card 500 is further prevented from moving in the second lateral/horizontal direction in the chassis 600 (block 816). In some embodiments, the third apparatus includes the bracket 300. Further, butting the brackets 200 and 300 against the graphics card 500, in accordance with certain embodiments, occurs at different heights on the graphics card 500 in blocks 812 and 816, respectively.

In some embodiments, the size of the bracket 200 is adjusted so that the graphics card 500 is able to be securely housed within the chassis 600 (block 818). In additional or alternative embodiments, the size of the bracket 300 is adjusted so that the graphics card 500 is further able to be securely housed within the chassis 600 (block 820).

In certain embodiments, adjusting the size of the bracket 200 and/or 300 can prevent the graphics card 500 from moving in a vertical/height direction (e.g., z-axis direction) in the chassis 600. Further, adjusting a size of the bracket 300 can create a space 604 between the chassis 600 and the graphics card 500.

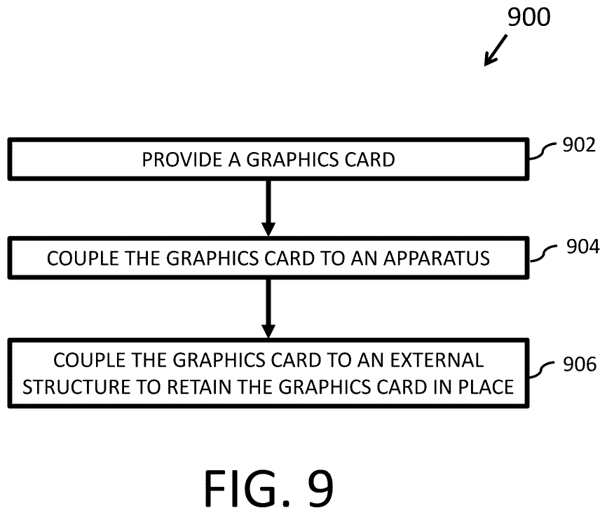

FIG. 9 is a schematic flow diagram of yet another embodiment of a method 900 for graphics card retention. At least in the illustrated embodiment, the method 900 begins by providing a graphics card 500 (block 902).

An apparatus is coupled to the graphics card 500 (block 904). In some embodiments, the apparatus includes the thermal bracket 100. In embodiments including the thermal bracket 100, the thermal bracket 100 includes a set of one or more mounting apertures 122 and a screw can be inserted through each mounting aperture 122 to couple/attach the thermal bracket 100 to the graphics card 500.

The graphics card 500 can then be coupled to an external structure (block 906). In some embodiments, the external structure includes the chassis 600.

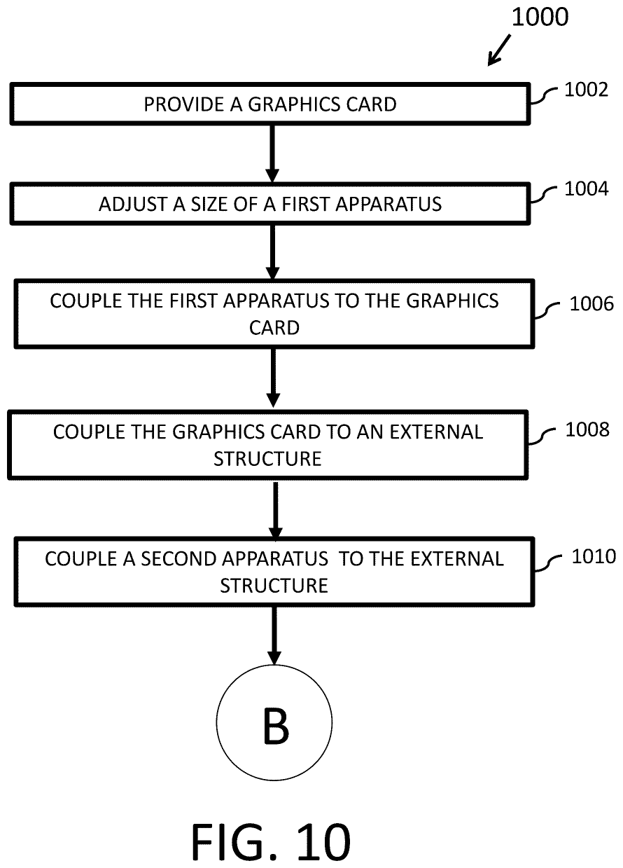

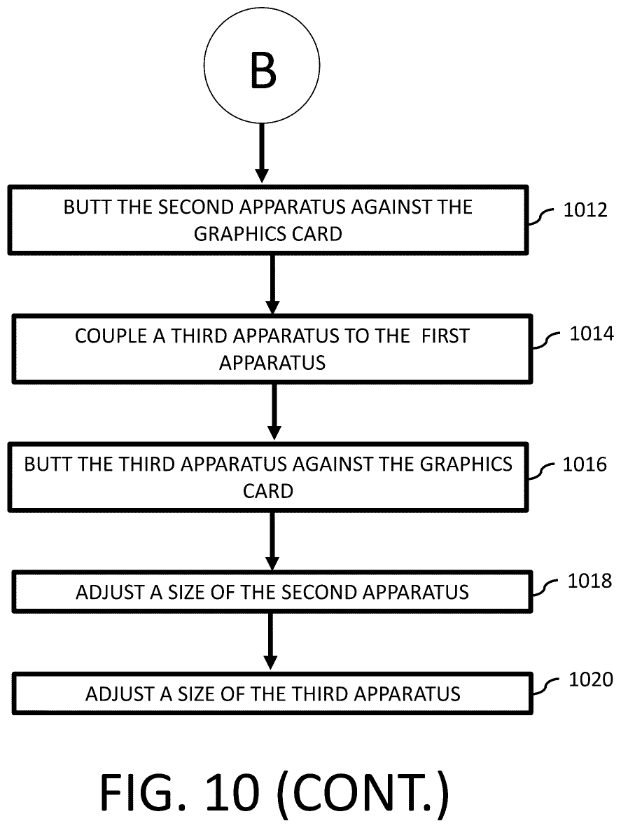

FIG. 10 is a schematic flow diagram of still another embodiment of a method 1000 for graphics card retention. At least in the illustrated embodiment, the method 1000 begins by providing a graphics card 500 (block 1002).

The size of a first apparatus is adjusted so that the graphics card 500 can be housed within an external structure (block 1004). In some embodiments, the first apparatus includes the thermal bracket 100 and the external structure includes the chassis 600.

The thermal bracket 100 is coupled to the graphics card 500 (block 1006) and the graphics card 500 is coupled to the chassis 600 (block 1008). In some embodiments, the thermal bracket 100 includes a set of one or more mounting apertures 122 and a screw can be inserted through each mounting aperture 122 to couple/attach the thermal bracket 100 to the graphics card 500. The graphics card 500 being coupled between the thermal bracket 100 and the chassis 600 prevents the graphics card 600 from moving in a first lateral/horizontal direction (e.g., an x-axis direction or a y-axis direction) in the chassis 600.

A second apparatus is coupled to the chassis 600 (block 1010) and butted against the graphics card 500 to retain the graphics card 500 within the chassis 600 and/or so that the graphics card 500 is prevented from moving in a second lateral/horizontal direction (e.g., an x-axis direction or a y-axis direction) in the chassis 600 that is perpendicular to the first lateral/horizontal direction (block 812). In some embodiments, the second apparatus includes the bracket 200.

A third apparatus is coupled to the thermal bracket 100 (block 1014) and butted against the graphics card 500 to retain the graphics card 500 within the chassis 600 and/or so that the graphics card 500 is further prevented from moving in the second lateral/horizontal direction in the chassis 600 (block 1016). In some embodiments, the third apparatus includes the bracket 300. Further, butting the brackets 200 and 300 against the graphics card 500, in accordance with certain embodiments, occurs at different heights on the graphics card 500 in blocks 1012 and 1016, respectively.

In some embodiments, the size of the bracket 200 is adjusted so that the graphics card 500 is able to be securely housed within the chassis 600 (block 1018). In additional or alternative embodiments, the size of the bracket 300 is adjusted so that the graphics card 500 is further able to be securely housed within the chassis 600 (block 1020). In certain embodiments, adjusting the size of the bracket 200 and/or 300 can prevent the graphics card 500 from moving in a vertical/height direction (e.g., z-axis direction) in the chassis 600. Further, adjusting a size of the bracket 300 can create a space 604 between the chassis 600 and the graphics card 500.

Embodiments may be practiced in other specific forms. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. An apparatus, comprising:
a trough including a bottom structure extending in a horizontal direction, a pair of side walls coupled to the bottom structure on opposite sides of the bottom structure and extending in a vertical direction and further extending in the horizontal direction, and an open side and top defining a cavity structure between the bottom structure and the pair of side walls; and
a retention bracket configured to:
slide along the pair of side walls in the horizontal direction to adjust a first size of the apparatus within a range of sizes to accommodate a graphics card including a second size within the range of sizes, and
maintain the graphics card in the horizontal direction in response to the retention bracket being butted against the graphics card.

2. The apparatus of claim 1, wherein:
the graphics card includes a cool air intake and a hot air exhaust; and
the retention bracket comprises a structural tab configured for location between the cool air intake and the hot air exhaust of the graphics card responsive to the retention bracket being coupled to the trough.

3. The apparatus of claim 2, wherein:
the structural tab extends vertically into the cavity structure of the trough responsive to the retention bracket being coupled to the trough; and
the structural tab forms a thermal divider between the cool air intake and the hot air exhaust of the graphics card responsive to the retention bracket being coupled to the trough and butting against the graphics card.

4. The apparatus of claim 1, wherein the retention bracket is detachably coupleable to the trough.

5. The apparatus of claim 1, wherein the retention bracket is permanently coupled to the trough.

6. A system, comprising:
a first apparatus including:
a trough, and
a retention bracket detachably coupleable to a graphics card, wherein:
the retention bracket is configured to slide along the trough in a first horizontal direction to adjust a length of the first apparatus within a range of lengths to accommodate the graphics card,
the graphics card includes a length size within the range of lengths, and
the retention bracket is further configured to maintain the graphics card in the first horizontal direction in response to the retention bracket being adjusted to include the length size and butt against a first width side of the graphics card when a second width side of the graphics card butts against an external structure;
a second apparatus including a length and coupleable to the external structure; and
a third apparatus coupleable to the retention bracket, wherein:
the graphics card includes a width size within a range of widths,
the second apparatus extends in a second horizontal direction perpendicular to the first horizontal direction in response to being coupled to the external structure,
the third apparatus is configured to slide along the retention bracket in the second horizontal direction to adjust a distance between the second apparatus and the third apparatus to be within the range of widths to accommodate the graphics card, and
the second apparatus and third apparatus maintain the graphics card in the second horizontal direction in response to the distance between the second apparatus and the third apparatus including the width size, the second apparatus butting against a first length side of the graphics card, and the third apparatus butting against a second length side of the graphics card.

7. The system of claim 6, wherein:
the length of the second apparatus is adjustable in the second horizontal direction; and
the distance between the second apparatus and the third apparatus is achieved in response to one of adjusting the length of the second apparatus in the second horizontal direction, sliding the third apparatus along the retention bracket in the second horizontal direction, or adjusting the length of the second apparatus in the second horizontal direction and sliding the third apparatus along the retention bracket in the second horizontal direction.

8. The system of claim 6, wherein:
the second apparatus is configured to butt against the graphics card at a first height;
the third apparatus is configured to butt against the graphics card at a second height; and
the first height and the second height are different heights.

9. The system of claim 6, wherein:
the graphics card includes a cool air intake and a hot air exhaust; and
the retention bracket comprises a structural tab configured for location between the cool air intake and the hot air exhaust of the graphics card responsive to the retention bracket butting against the trough.

10. The system of claim 9, wherein:
the structural tab extends vertically into the cavity structure of the trough responsive to the retention bracket being coupled to the trough; and
the structural tab forms a thermal divider between the cool air intake and the hot air exhaust of the graphics card responsive to the retention bracket being coupled to the trough and butting against the graphics card.

11. The system of claim 6, wherein the retention bracket is detachably coupleable to the trough.

12. The system of claim 6, wherein the retention bracket is permanently coupled to the trough.

13. The system of claim 6, wherein the external structure comprises a chassis.

14. The system of claim 13, wherein the chassis comprises one of a Peripheral Component Interconnect (PCI) chassis or a PCI Express chassis.

15. A method comprising:
providing a graphics card;
coupling the graphics card to an external structure; and
butting a first apparatus against the graphics card,
wherein:
the first apparatus comprises a trough and a retention bracket configured to adjustably slide along the trough, and
butting the first apparatus against the graphics card secures the graphics card in place between the external structure and the first apparatus within the external structure.

16. The method of claim 15, further comprising adjusting the first apparatus by sliding the retention bracket along the trough to accommodate a size of a range of sizes for the graphics card in a first horizontal direction.

17. The method of claim 16, further comprising:
coupling a second apparatus to the external structure; and
butting the second apparatus against the graphics card, wherein:
the second apparatus extends in a second horizontal direction perpendicular to the first horizontal direction in response to being coupled to the external structure, and
the second apparatus includes an adjustable length in the second horizontal direction to adjust a first distance between the second apparatus and the external structure.

18. The method of claim 17, further comprising:
coupling a third apparatus to the retention bracket, wherein:
the graphics card further includes a width size within a range of widths, a first length side, and a second length side,
the third apparatus is configured to adjustably slide along the retention bracket in the second horizontal direction to adjust a second distance between the second apparatus and the third apparatus to be within the range of widths to accommodate the graphics card, and
the second apparatus and third apparatus maintain the graphics card in the second horizontal direction in response to the second distance between the second apparatus and the third apparatus including the width size, the second apparatus butting against the first length side of the graphics card, and the third apparatus butting against the second length side of the graphics card.

19. The method of claim 18, further comprising performing at least one of adjusting the length of the second apparatus in the second horizontal direction or sliding the third apparatus along the retention bracket in the second horizontal direction to adjust the second distance between the second apparatus and the third apparatus to be within the range of widths to accommodate the graphics card.

20. The method of claim 18, further comprising:
coupling the first apparatus to the graphics card via a set of one or more mounting apertures in the first apparatus,
wherein:
coupling the second apparatus to the external structure comprises coupling the second apparatus to the external structure at a first height;
coupling the third apparatus to the retention bracket comprises coupling the third apparatus to the retention bracket at a second height; and
the first height and the second height are different heights.
